(19) United States
(12) Patent Application Publication
(10) Pub. No.: US 2023/0062807 A1
(43) Pub. Date: Mar. 2, 2023

(54) FAN FRAME ELECTRICAL CONNECTOR STRUCTURE

(71) Applicant: ASIA VITAL COMPONENTS CO., LTD., New Taipei City (TW)

(72) Inventors: Sung-Wei Sun, New Taipei City (TW); Ming-Che Lee, New Taipei City (TW)

(21) Appl. No.: 17/465,806

(22) Filed: Sep. 2, 2021

(51) Int. Cl. H05K 7/20; H01R 12/70; H01R 12/71; F04D 17/08; F04D 29/42

(52) U.S. Cl. CPC H05K 7/20172; H01R 12/7076; H01R 12/714; F04D 17/08; F04D 29/4226; H01R 13/2407

(57) ABSTRACT

A fan frame electrical connector structure is configured for assembling to a motherboard of an electronic device and includes a fan having a frame. The frame is provided with at least one pogo pin connector, which is located at one side of the frame to project into an outer side of the frame. The motherboard of the electronic device is provided at a position corresponding to the pogo pin connector with at least one metal contact, and the pogo pin connector is electrically connected to the metal contact. With the above fan frame electrical connector structure, it is possible to realize automated assembling of the fan to the electronic device motherboard.

### FIELD OF THE INVENTION

The present invention relates to a fan frame electrical connector structure, and more particularly, to a fan frame electrical connector structure that enables automated assembling of a fan to a motherboard of an electronic device.

### BACKGROUND OF THE INVENTION

A fan is a common system heat dissipation device frequently applied to an electronic device to provide the effect of forced heat dissipation. Generally, the fan is electrically connected to a motherboard of the electronic device to receive transmitted signal and power in order to obtain required power supply and achieve signal feedback control.

Please refer to FIG. 1, in which a conventional centrifugal fan 3 is shown. The conventional fan 3 includes a connector 4, which is electrically connected to a plurality of metal terminals 5 provided on an electronic device motherboard. And the connector 4 is electrically connected to a circuit substrate (not shown) of the fan 3 via a plurality of electro-conductive wires 41. The connector 4 is connected to outer ends of the electro-conductive wires 41 and is dangling at an outer side of the fan 3. After the fan 3 has been fixed to the electronic device motherboard, the dangling connector 4 has to be manually plugged onto the corresponding metal terminals 5 on the electronic device motherboard to complete the entire assembling of the fan 3 to the electronic device motherboard. However, the electro-conductive wires 41 exposed from the fan 3 form some redundant sections (i.e. excessive lengths of the electro-conductive wires 41) between the fan 3 and the electronic device motherboard 5 to interfere with smooth airflow in the internal space of the system and cause dust absorption or dustfall.

In view that the conventional fan and the electronic device motherboard must be manually assembled to consume a lot of labor and time to result in increased manufacturing cost and inconsistent assembling quality, it is an important goal of persons skilled in the art to solve this problem.

### SUMMARY OF THE INVENTION

A primary object of the present invention is to effectively solve the above problem by providing an improved fan frame electrical connector structure that enables automated assembling of a fan to the motherboard of an electronic device.

To achieve the above and other object, the fan frame electrical connector structure according to the present invention is configured for correspondingly assembling to a motherboard of an electronic device and includes a fan.

The fan includes a frame having at least one pogo pin connector provided thereon. The pogo pin connector is provided on one side of the frame to project into an outer side of the frame. The motherboard of the electronic device is provided at a location corresponding to the pogo pin connector with at least one metal contact. The pogo pin connector is electrically connected to the metal contact.

The pogo pin connector is selectively provided on a base seat or a sidewall of the frame, so that the frame can be assembled to the electronic device motherboard in an axial or vertical direction or in a radial or horizontal direction. The electronic device motherboard is provided at a position corresponding to the pogo pin connector with at least one metal contact, and the pogo pin connector is electrically connected with the metal contact.

With the fan frame electrical connector structure of the present invention, the fan can be picked up by a robot arm and other tools to be directly electrically connected to and assembled to the electronic device motherboard at the same time to thereby realize the object of automated assembling of the fan to the electronic device motherboard.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 shows a conventional centrifugal fan;

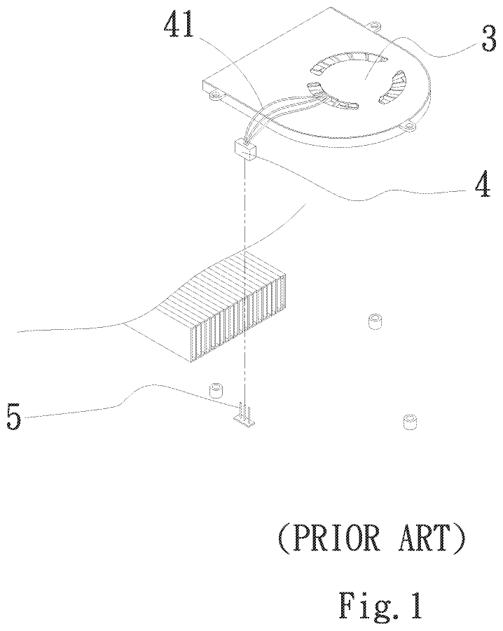

FIG. 2 is partially exploded perspective view of a fan frame electrical connector structure according to a preferred embodiment of the present invention; and

FIG. 3 is an assembled sectional view of the fan frame electrical connector structure according to the preferred embodiment of the present invention.

### DETAILED DESCRIPTION OF THE PREFERRED EMBODIMENTS

The present invention will now be described with some preferred embodiments thereof and by referring to the accompanying drawings.

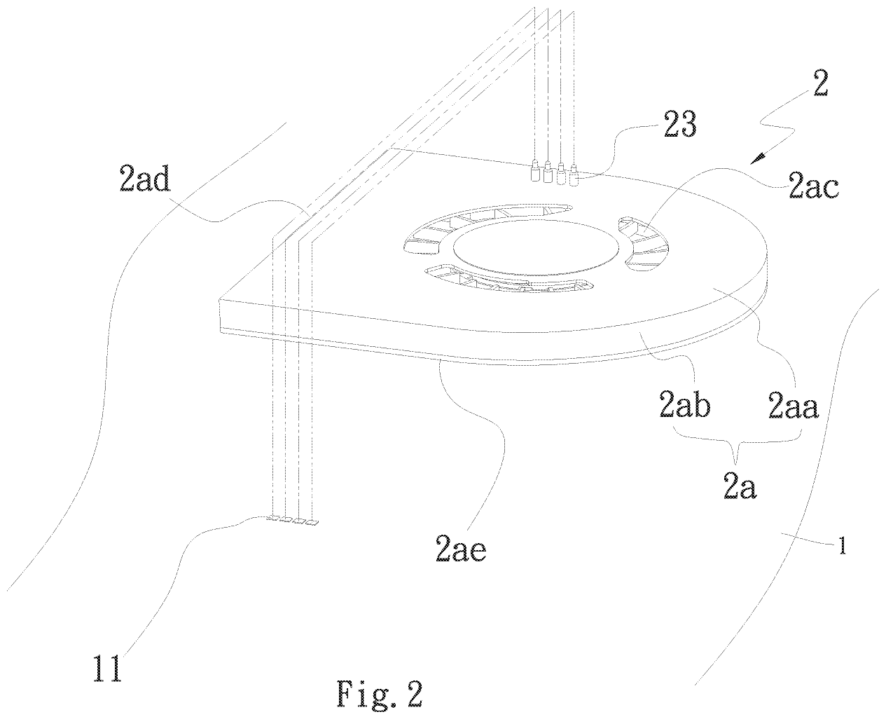

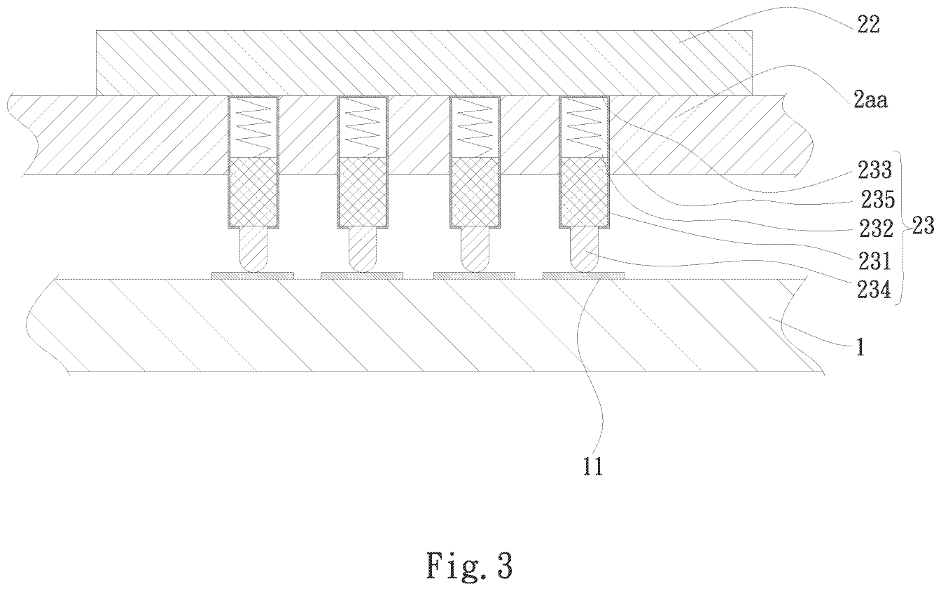

Please refer to FIGS. 2 and 3, which are partially exploded perspective view and assembled sectional view, respectively, of a fan frame electrical connector structure according to the preferred embodiment of the present invention. As shown, the fan frame electrical connector structure of the present invention is configured for correspondingly assembling to a motherboard 1 of an electronic device and includes a fan 2.

The fan 2 includes a frame 2a, a circuit substrate 22, and at least one pogo pin connector 23. The pogo pin connector 23 includes a main body 231, which internally defines a receiving space 232 and has a connecting end 233 electrically connected to the circuit substrate 22. In the receiving space 232, there is provided a plunger 234 and a spring 235. The plunger 234 has an end projected beyond the receiving space 235 of the main body 231 and another end pressed against the spring 235, such that the plunger 234 is reciprocatingly movable in the receiving space 232 relative to the main body 231. The circuit substrate 22 can be a rigid circuit board, a flexible circuit board or any other suitable circuit board.

The frame 2a has a wind inlet 2ac and a wind outlet 2ad. In the illustrated embodiment, the frame 2a is a frame for a centrifugal fan and includes an upper cover 2ae. The wind inlet 2ac is provided on the upper cover 2ae, while the wind outlet 2ad is provided on an upper side and a lateral side (i.e. a sidewall 2ab) of the fan 2a. And, the wind inlet 2ac and the wind outlet 2ad are oriented to two directions perpendicular to each other.

In another operable embodiment, the frame 2a is a frame for an axial fan. In this case, the wind inlet 2ac and the wind outlet 2ad are provided on an upper side and a lower side (not shown) of the frame 2a, respectively. While the present invention is described with an embodiment of a centrifugal fan, it is understood the present invention is not particularly limited thereto.

The frame 2a further has a stator and a rotor provided thereon. Since the stator and the rotor are the same as those in the conventional fan, they are not repeated described herein.

The frame 2a also includes a base seat 2aa and a sidewall 2ab, which are connected together to form the frame 2a. The pogo pin connector 23 is selectively provided on the base seat 2aa or the sidewall 2ab of the frame 2a to project into an outer side of the frame 2a, such that the pogo pin connector 23 is vertically projected from the base seat 2aa or horizontally projected from the sidewall 2ab for connecting with the electronic device motherboard 1. The circuit substrate 22 can be selectively provided on any one of the base seat 2aa and the sidewall 2ab of the frame 2a.

For the purpose of assembling the fan 2 of the present invention to the motherboard 1, a mount is provided on the motherboard 1 corresponding to a location for mounting the fan 2. Then, the fan 2 and the motherboard 1 can be connected to each other by different means, such as screw fastening, clamping or snap-fitting. It is understood the present invention is not particularly limited thereto. Since these assembling means and structures are generally known, they are not repeatedly described herein.

The main purpose of the present invention is to overcome the disadvantage that the connector on the conventional fan could not be plugged onto the connector on the electronic device in an automated manner when the fan is to be electrically connected and assembled to the motherboard of the electronic device. In the present invention, the pogo pin connector is directly provided on the base seat or the sidewall of the fan frame to project therefrom for electrically connecting to the metal contact correspondingly provided on the electronic device motherboard. Therefore, the fan can be directly picked up and moved by a robot arm with or without other tools to the position for electrically assembling and fixing to the electronic device motherboard at the same time.

The present invention solves the problem in the conventional fan that the could not be electrically connected to and assembled to the electronic device motherboard at the same time, it not only largely saves the labor cost but also reduces the time required and the error rate occurred in the fan assembling operation.

The present invention has been described with a preferred embodiment thereof and it is understood that many changes and modifications in the described embodiment can be carried out without departing from the scope and the spirit of the invention that is intended to be limited only by the appended claims.

1. A fan frame electrical connector structure configured for correspondingly assembling to a motherboard of an electronic device, comprising:
a fan including a frame having a base seat and a sidewall and a circuit substrate disposed on the base seat of the frame, the circuit substrate having at least one pogo pin connector provided thereon; the pogo pin connector being provided on the base seat of the frame to project into an outer side of the frame, and the motherboard of the electronic device being provided with at least one metal contact at a location corresponding to the pogo pin connector, the at least one pogo pin connector including a main body which internally defines a receiving space and has a connecting end electrically connected with the circuit substrate, the receiving space having a plunger and a spring provided therein, the plunger having an end projected beyond the receiving space of the main body and another end pressed against the spring such that the plunger is reciprocatingly movable in the receiving space relative to the main body; and the pogo pin connector being electrically connected to the metal contact.

2-4. (canceled)

5. The fan frame electrical connector structure as claimed in claim 1, wherein the frame is provided with a wind inlet and a wind outlet, and is internally provided with a rotor and stator.

6. The fan frame electrical connector structure as claimed in claim 5, wherein the frame is a frame for an axial fan, and the wind inlet and the wind outlet being provided on an upper and a lower side of the frame, respectively.

7. The fan frame electrical connector structure as claimed in claim 5, wherein the frame is a frame of a centrifugal fan and includes an upper cover; the wind inlet being provided on the upper cover, and the wind outlet being provided at a lateral side of the frame; and the wind inlet and the wind outlet being oriented to two directions perpendicular to each other.
